(19) United States
(12) Patent Application Publication
(10) Pub. No.: US 2025/0128475 A1
(43) Pub. Date: Apr. 24, 2025

(54) Method for Real-Time Controlled Selective Irradiation of a Predetermined Dose Onto a Target Zone of a Surface, and Corresponding System

(71) Applicant: EBICA, BOUAYE (FR)

(72) Inventor: Stéphane ETIENNE, BOUAYE (FR)

(21) Appl. No.: 18/920,466

(22) Filed: Oct. 18, 2024

(30) Foreign Application Priority Data
Oct. 20, 2023 (FR) 2311413

(51) Int. Cl. B29C 64/393; B29C 64/282; B33Y 10/00; B33Y 50/02

(52) U.S. Cl. CPC B29C 64/393; B29C 64/282; B33Y 10/00; B33Y 50/02

(57) ABSTRACT

A method for controlled selective irradiation of a target zone of a surface to allow local radiation of this target zone to obtaining a target effect. The method is implemented by a system including an emitter device, at least one measurement and analysis device and a controller device. The method includes: measuring and recording in real time the real main energy at the target zone; analyzing and recording the real effect obtained at this target zone; and controlling in real time the emitter device by the controller device, while taking into account the measurement of the real main energy and the analysis of the real effect, which are compared respectively to a predetermined energy threshold associated with the target zone and to the expected target effect, so that, if the predetermined energy threshold is not reached but the target effect is obtained, the irradiation of the target zone is stopped.

### CROSS REFERENCE TO RELATED APPLICATION

This application claims priority to and the benefit of French Patent Application No. FR2311413, filed Oct. 20, 2023, the entire contents of which are incorporated herein by reference.

### TECHNICAL FIELD OF THE INVENTION

The present invention relates to the general field of irradiation of surfaces by energy radiation.

The invention relates more particularly to a method for controlled selective irradiation of a target zone of a surface implementing a system comprising an emitter programmable device, at least one measurement and analysis device and a controller device, these devices being connected to each other in a closed loop. In this method, the controller device controls in real time the emitter device during the irradiation process, according to the data relative to the real energy measured at the irradiated target zone and the real effect obtained at this target zone. This method according to the invention is also capable of taking into account the collateral energies measured around the irradiated target zone.

### TECHNICAL BACKGROUND

Irradiation methods, in particular adapted to the field of additive manufacturing, are known to a person skilled in the art. Thus, mention can be made of the method described in the patent application DE102015216583 A1, which is implemented by an irradiation system comprising on the one hand a source emitting energy radiation such as laser beams, and on the other hand a control device configured to adjust the source emitting radiation according to the object to be manufactured. This adjustment of the emitting source by the control device is a function of parameters previously inputted into the control device: the latter can thus control the emitting source so that it reaches the predetermined energy parameters that are associated with it.

However, such a method has the disadvantage of not being able to take into account the real progress in the manufacturing of the object, and thus control the emitting source according to predetermined data and at the same time data measured in real time.

To overcome this disadvantage, new methods for additive manufacturing by irradiation were developed: mention can be made in particular of the method disclosed in the patent EP3311983 B1, which is capable of controlling in real time the emitting source during the irradiation, to adapt to the real object being manufactured. For this, the irradiation method of EP3311983 B1 is implemented by an irradiation system that further comprises a device capable of measuring the energy emitted by the radiation of the emitting source at the irradiated zone, and of transmitting this measured data to the control device. This control device is thus capable of adapting the power and/or the intensity of the energy radiation emitted by the emitting source during the irradiation process so that the energy effectively emitted does not deviate from the base energy parameters.

However, although this method allows a control in real time of the emitting source, it still does not allow to control this emitting source so that it is capable of taking into account the result effectively expected, outside of the base energy parameters: the control device is thus not capable of controlling the emitting source so that:
it stops when the manufacturing of the expected product is finished, even if the base parameters have not been reached, or
the source continues to emit energy radiation even though the base parameters have been reached (the manufacturing of the expected product not being finished). In the method of EP3311983 B1, the power or the energy intensity of the emitting source can be adjusted, and in particular reduced, or even turned off, if the control device determines that the threshold energy dose has been reached, or inversely, increased to reach this threshold. But the method of EP3311983 B1 does not allow the control device to determine whether the base energy parameters effectively allow to reach the expected final result. As a result, such an irradiation system has the disadvantage either of engendering losses of energy and of time, if the emitting source continues to emit radiation even though the final result has already been achieved, or of not achieving the desired result, if the source stops since it has reached the base energy parameters, but the final result has not been achieved.

There is therefore a need for new methods and systems for irradiation by energy radiation that adapt in an efficient manner in real time to the result effectively obtained at the irradiated surface, while allowing to reduce the losses.

### SUMMARY OF THE INVENTION

For this purpose, the invention proposes, according to a first object, a method for controlled selective irradiation of a target zone of a surface of a product or of a given living being, to allow the local radiation of this target zone with a view to obtaining a target effect, this method being implemented by a system comprising an emitter device, at least one measurement and analysis device and a controller device. This method comprises the following steps:
A) segmenting the surface into a plurality of zones;
B) inputting into the controller device predetermined main energy thresholds respectively associated with each of the zones, and inputting the target effect to be obtained;
C) choosing the target zone among the zones and their combinations;
D) irradiating the target zone by emission of energy radiation by the emitter device, this emission being controlled by the controller device with the goal of reaching the predetermined main energy thresholds;
E) measurement and recording in real time, by the measurement and analysis device, of the real energy generated by the energy radiation at the target zone;
F) analysis and recording, by the measurement and analysis device, of the real effect obtained at the irradiated target zone;
G) transmitting the measurement of the real energy and the analysis of the real effect to the controller device;
H) control in real time of the emitter device by the controller device during the irradiation method, while taking into account the measurement of the real energy and the analysis of the real effect received,
the measurement of real energy being compared to the predetermined main energy threshold associated with the target zone C, and the analysis of the real effect being compared to the target effect, so that:
   H1) if the main energy threshold is not reached and the target effect is not obtained, the emission of energy radiation onto the target zone continues and the power and/or the intensity of the energy radiation is modulated to obtain the target effect O;
   H2) if the main energy threshold is reached but the target effect is not obtained, the emission of energy radiation onto the target zone continues and the power and/or the intensity of the energy radiation is modulated to obtain the target effect;
   H3) if the main energy threshold is reached and the target effect is obtained, the emission of energy radiation onto the target zone is stopped;
   H4) if the main energy threshold is not reached but the target effect is obtained, the emission of energy radiation onto the target zone is stopped.

Such a method according to the invention thus allows to control the irradiation in real time of a target zone, while taking into account energy and target effect base parameters, but also while taking into account the real energy felt at the target zone and the real effect obtained at this zone. Thus, contrary to the irradiation methods of the prior art, according to the method of the invention, the predetermined energy parameters, which act as a guide to carry out the irradiation process, are not necessarily reached when this is not useful: indeed, this method according to the invention is capable of determining that the irradiation can be stopped since the target effect, which is analysed in parallel to the measurement of the real energy, has already been obtained, even though the real energy parameters do not exactly correspond to the base energy parameters. Inversely, according to the method of the invention, and still contrary to the irradiation methods of the prior art, it can be determined that the effective irradiation of the target zone must continue, even though the predetermined parameters have already been reached, which allows to obtain the expected effect in a certain manner. Moreover, if a comodality of trends in the corrective parameters is validated, the initial parameters are self-corrected. This modulation of the energy parameters in real time, and in particular the stopping of the emission of the energy radiation as soon as it is determined that the target effect has been obtained, advantageously allows to reduce the energy and financial losses usually linked to the conventional irradiation methods, since the continuous and useless irradiation of the target zone for which the target effect has already been reached is limited, or even eliminated.

Moreover, being able to concentrate the irradiation on a determined target zone allows to locally irradiate only the required surface, while minimising, or even while eliminating, the peripheral irradiation, which is one of the main causes of energy and financial losses in the known irradiation methods. This advantage is also very clearly illustrated in the health field, for example by the minimisation of the risks of burns at the zones surrounding the irradiated target zone.

To improve control of the irradiation of a target zone, it is also possible to enter duration parameters in the controller device. For example, the duration parameters may be representative of a minimum duration of irradiation, in order to ensure that the target zone is at least irradiated during this minimum duration. It should be noted that the minimum duration of irradiation preferably corresponds to a predetermined duration allowing achieving the expected target effect. In particular, this minimum duration depends on the conditions of irradiation, i.e. the power and/or the intensity of the radiation emitted by the emitter device during irradiation of the target zone. Such a method can be implemented in all the fields that involve the irradiation of a material for a given purpose. Thus, for example, this method can be implemented in the microelectronics field, to manufacture semiconductor parts by additive manufacturing: the target effect corresponds in this case to the solidification of at least a portion of a layer of material according to a method for polymerisation by irradiation. This method can also be implemented in the medical field: the effect corresponds in this case to the destruction of a tumour by irradiation. This method can also be implemented in the cosmetics field, in particular in nail care: the target effect corresponds in this case to the solidification of a layer of polish on a nail via polymerisation by irradiation.

According to one embodiment, the method according to the invention further comprises the following steps:
A′) inputting into the controller device predetermined secondary energy thresholds respectively associated with each of said zones;
B′) measurement and recording in real time, by the measurement and analysis device, of the collateral real energy, generated at least at one zone of the plurality of zones that is adjacent to the target zone, this collateral real energy being generated by the energy radiation irradiating the target zone;
C′) transmitting the measurement of the collateral real energy to the controller device;
D′) control in real time of the emitter device by the controller device during the irradiation method, while taking into account the measurement of the collateral real energy,
this measurement of the collateral real energy being compared to the predetermined secondary energy threshold associated with the at least one zone of the plurality of zones that is adjacent to the target zone, so that:
if the secondary energy threshold of the at least one zone adjacent to the target zone is reached, the power and/or the intensity of the energy radiation irradiating the target zone C are modulated to reduce the collateral real energy.

It is thus also possible, according to the method of the invention, to modulate the emitting source according to secondary parameters, and in particular according to the collateral energy felt and measured at the zones adjacent to the irradiated target zone. In the same way as for the control of the emitting source according to the real energy measured at the irradiated target zone, the system of the invention is capable of comparing the real energy of the zones adjacent to the target zone to energy thresholds at these zones, which correspond to “secondary” thresholds, taken into account when the zones associated with these thresholds are not target zones, but zones collateral to the target zone. The method according to the invention thus advantageously allows a very precise control of the irradiation of the target zone, according to parameters of various levels (main and secondary), which are not necessarily linked to the zone effectively irradiated.

According to one embodiment, the method according to the invention further comprises the following steps, when the layer of material is deposited over a substrate:
I) entering into the controller device a maximum energy threshold associated with the substrate;
J) measuring and recording in real time, by the measurement and analysis device, the effective energy generated at the substrate;
K) transmitting the measurement of the effective energy to the controller device;
L) controlling the emitter device in real time by the controller device during the irradiation process, while taking into account the measurement of the effective energy,
the measurement of the effective energy being compared to the maximum energy threshold, so that, if the effective energy is higher than the maximum energy threshold, the power and/or the intensity of the energy radiations irradiating the target zone (C) are modulated to reduce the effective energy at the substrate.

Thus, the method according to the invention is capable of analysing the state of the zone of the layer of material that is irradiated and simultaneously analysing the state of the substrate over which this layer of material is deposited. Hence, this method advantageously allows irradiating a zone of a layer of a first material while taking into account the state of a layer of a second material present in the environment of this first layer, and modulating this irradiation operation in order to preserve this second layer of material. For example, in the case where the irradiated layer of material is deposited over an electronic substrate, to form an electronic compound, this irradiation process taking into account the electronic substrate allows polymerising the layer of material at surface and not damaging the electronic compound.

According to one embodiment, the method according to the invention further comprises the following steps:
I′) entering in the controller device an intermediate energy threshold associated with the substrate, as well as a maximum duration associated with the intermediate energy threshold;
M) controlling the emitter device in real time by the controller device, during the irradiation process, while taking into account the measurement of the effective energy,
the measurement of the effective energy being compared to the intermediate energy threshold, and when the effective energy corresponds to the intermediate energy threshold, the measurement and analysis device measures and records in real time an effective duration corresponding to the duration during which the effective energy corresponds to the intermediate energy threshold, and the controller device compares the effective duration to the maximum duration, so that, if the effective duration is longer than the maximum duration, the power and/or the intensity of the energy radiations irradiating the target zone are modulated to reduce the effective energy at the substrate.

Hence, this method according to the invention is advantageously capable of implementing a fine and accurate analysis of the state of the substrate. This makes it possible to implement, in real time, effective irradiation of the layer of material covering this substrate which is adapted to the environment in which this layer of material is integrated.

According to a specific embodiment, the target zone corresponds to the totality of the surface.

The method according to the invention, which allows to control the emitter device in real time, allows to irradiate only a part of the target zone, or the entirety thereof.

According to a specific embodiment, the emitter device is stationary and chosen from an array comprising a plurality of independent emitting sources and at least one emitting source associated with an optical galvanometer.

By array, in the context of the invention, it should be understood a support element or a frame, allowing integrating a plurality of emitting sources.

Thus, when the emitter device is an array comprising a plurality of independent emitting sources, the control of the emitter device by the controller device can correspond to the activation and/or the deactivation of one or more of the multiple emitting sources composing the emitter device, according to the real energy measured and the real effect analysed at the target zone. For example, the method according to the invention allows the controller device to reduce the power and/or the energy intensity of certain emitting sources of the emitter device, or even to deactivate some of them, if the controller device determines that the real energy at certain portions of the target zone is close to, or even reaches or exceeds, the predetermined main energy threshold, and that the target effect is close to being obtained, or even has already been obtained. Inversely, this irradiation method also allows the controller device to increase the power and/or the energy intensity of certain emitting sources of the emitter device, or even to activate some of them, if the controller device determines that the real energy at certain portions of the target zone is less than the predetermined main energy threshold, and that the target effect has not been obtained. For example, the emitting source that is associated with the optical galvanometer is a laser source.

According to a specific embodiment, when the emitter device is an array comprising a plurality of independent emitting sources, these independent emitting sources being LEDs. LEDs are devices easy to integrate into the system of the invention, simple to implement and to manipulate, and not very costly.

According to another embodiment, the emitter device consists of a plurality of emitting sources associated with one single optical galvanometer.

According to an example of this embodiment, such an emitter device consists of several emitting sources which are laser sources, for example three, four, five or six laser sources, and one single optical galvanometer. Preferably, all of the emitting sources are integrated into the same support array.

Preferably, each of these laser sources is defined by different properties, in particular in terms of wavelength of the emitted radiation. The laser sources are independent of each other, and are, for example, modulated independently of each other.

According to another example of this embodiment, such an emitter device consists of five laser sources arranged at 72° with respect to each other, according to a circle shape, and of an optical galvanometer integrated at the centre of this circle.

In the system of the invention according to these two examples, the optical galvanometer is, in particular, configured to combine the energy radiations emitted by each of the emitting sources into one single energy radiation. The galvanometer is also configured to deflect the unique energy radiation towards a target zone of the surface to be irradiated.

According to one embodiment, the emitter device is mobile, such as a mobile source mounted on an axis.

According to a specific embodiment, the measurement and analysis device is a thermal and/or radiative imaging sensor, associated with an image analysis module.

Thus, the measurement and analysis device implemented in the irradiation method according to the invention is capable of measuring both the real energy at the target zone and the real energy at the zones adjacent to the target zone, and of analysing the progress/the state of the real effect at the target zone, while avoiding damaging the target.

It can thus transmit these two types of data to the controller device, which is thus capable of determining how to control the emitter device to reach the predetermined energy thresholds and at the same time the expected target effect.

According to a specific embodiment, the controller device is a human-machine interface. Such an interface is easy to integrate into the system of the invention, and easy to implement and to manipulate.

According to a specific embodiment, the energy radiations are chosen from the radiation of visible light, infrared, gamma, ultraviolet, laser, microwaves, X-rays, and convective or conductive thermal deployment.

The method according to the invention can thus advantageously adapt to any type of irradiation, and can, according to at least one embodiment, combine them.

According to a second object, the invention proposes a system for controlled selective irradiation of a target zone of a surface of a product or of a given living being, segmented into a plurality of zones, this system implementing the method as described above, and comprising:
an emitter device, configured to irradiate the target zone by energy radiation,
at least one measurement and analysis device, configured to measure the real energy generated by the energy radiation at the target zone and the collateral real energy generated at least at one zone of the plurality of zones that is adjacent to the target zone, as well as to analyse the real effect obtained at the irradiated target zone,
a controller device, configured to receive main and secondary predetermined energy thresholds, respectively associated with each of the zones and a target effect to be obtained, as well as to receive the measurement of the real energy and of the collateral real energy generated at least at one zone of the plurality of zones that is adjacent to the target zone, as well as the analysis of the real effect,
the controller device comprising means for comparing the measurement of real energy to the predetermined main energy threshold associated with the target zone, the measurement of the collateral real energy to the predetermined secondary energy threshold of the at least one zone adjacent to the target zone, and the analysis of the real effect to the target effect,
the controller device being further configured to control the emitter device in real time during the irradiation method by stopping the emission of the energy radiation, and/or by modulating the power and/or the intensity of the energy radiation, and/or by selective modulation of the irradiated zones.

This system has at least the same advantages as those presented in relation to the corresponding method. It corresponds to a closed loop, which is advantageously entirely traceable.

According to one embodiment, the measurement and analysis device of the system is further configured to measure the effective energy at a substrate over which the layer of material has been deposited, and wherein the controller device is further configured to receive a maximum energy threshold associated with the substrate, the controller device further comprising means for comparing the effective energy measurement to the maximum energy threshold.

According to a particular embodiment, the controller device of the system is further configured to receive an intermediate energy threshold associated with the substrate and a maximum duration associated with the intermediate energy threshold, the controller device further comprising means for comparing the effective energy measurement to the intermediate energy threshold, and wherein, when the effective energy corresponds to the intermediate energy threshold, the measurement and analysis device is further configured to measure the effective duration during which the effective energy corresponds to the intermediate energy threshold, and the controller device further comprising means for comparing the effective duration to the maximum duration of irradiation.

Thus, the system according to the invention is capable of analysing the irradiated layer of material and simultaneously analysing the substrate on which it rests, and that being so in an accurate manner, in order to enable control of the irradiation in real time by the emitter device allowing polymerising the layer material at surface without damaging the substrate, and even without damaging the element or the compound that comprises this irradiated layer of material/substrate set.

According to a specific embodiment, the measurement and analysis device comprises:
at least one measurement and recording means configured to measure the real energy generated by the energy radiation at the target zone, and the collateral real energy at least at one zone adjacent to the target zone, and, when the measurement and analysis device is further configured to measure the effective energy at the substrate, the measurement and recording means is further configured to measure the effective energy and the effective duration at the substrate, and
at least one analysis and recording means configured to analyse the real effect obtained at the irradiated target zone.

This device thus plays an important role in being able to take into account the real energy felt at the target zone and at the same time the state of the real effect at this zone. During the irradiation method, these two types of data are compared to the base equivalent data, via the controller device, which is thus capable of determining whether or not the expected target effect is effectively obtained at the target zone, and which can consequently control the emitter device on demand with the final goal of obtaining the target effect on the target zone. Moreover, the secondary parameters, relative to the zones adjacent to the target zone effectively irradiated, as well as the parameters relating to the substrate on which the irradiated layer of material rests, are also monitored, in order to ensure that the variations in parameters of the emitting source do not affect the integrity of the target. An analysis of trends in the variations in parameters of the target (AI) is carried out by iterations in order to adjust the predetermined parameters.

### BRIEF DESCRIPTION OF THE DRAWINGS

Other features and advantages of the invention will appear during the reading of the following detailed description for the understanding of which reference will be made to the appended drawing in which:

FIG. 1 schematises the controlled selective irradiation system according to an embodiment of the invention;

FIG. 2 schematises the controlled selective irradiation system according to another embodiment of the invention;

FIG. 3 schematises the controlled selective irradiation system according to still another embodiment of the invention.

### DETAILED DESCRIPTION OF THE INVENTION

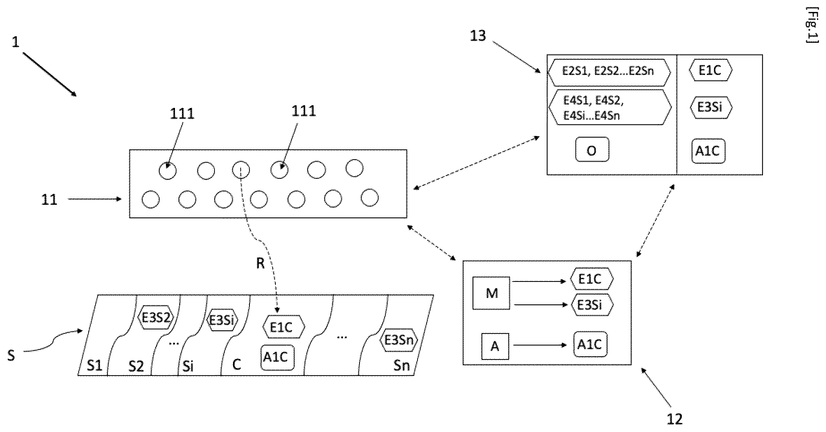

The method for controlled selective irradiation is implemented by an irradiation system 1 as illustrated in FIG. 1. Such a system comprises an emitter device 11, at least one measurement and analysis device 12 and a controller device 13, which function in a closed loop. In general, the measurement and analysis device 12 measures the real energy data and analyses the real effect at the target zone, when the emitter device 11 irradiates energy radiation at this target zone. It then transmits these two types of data to the controller device 13, which is thus capable of controlling the emitter device 11 by modulating the energy parameters of the energy radiation emitted by the latter, while taking into account the predetermined parameters with which it was loaded (energy thresholds and expected effect) and the real data transmitted by the measurement and analysis device 12.

In the embodiment of FIG. 1, the emitter device 11 emits energy radiation R at a target zone C to be irradiated, belonging to a surface S which is composed of a plurality of zones S1, S2. . . . Si. . . . Sn. In other embodiments of the invention, the target zone can correspond to the combination of several zones of the plurality of zones S1, S2. . . . Si. . . . Sn of the surface to be irradiated, and can also correspond to the entirety of the surface S, that is to say include all of the plurality of zones that compose this surface S. The emission of energy radiation R onto the target zone C produces a real energy E1C at this target zone, which can be measured by the method of the invention.

In this embodiment, the emitter device 11 corresponds to an array that comprises a plurality of independent emitting sources 111. These sources 111 can be activated or deactivated independently of each other by the controller device 13 of the system, according in particular to the real energy E1C measured at the irradiated target zone C, as well as the real effect A1C obtained at this zone, this real data being compared to predetermined data, corresponding to predetermined energy thresholds and to the expected final effect at the surface to be irradiated. According to one example, these independent sources 111 are LEDs.

According to other embodiments, not illustrated, the emitter device 11 can be a mobile source on board an axis XY (Z), capable of moving along this axis, or a source positioned in a static manner and reoriented towards the target zone to be irradiated by an optical galvanometer.

The real energy E1C and the real effect A1C at the target zone C are measured and analysed by the measurement and analysis device 12 of the system. For this, this device 12 comprises at least one measurement and recording means M for measuring the real energy E1C at the irradiated target zone C, as well as at least one analysis and recording means A for analysing the real effect A1C at this zone. According to a specific example, this device 12 corresponds to a camera that comprises as a measurement and recording means M a thermal device, for measuring the temperature at the irradiated target zone, which temperature corresponds to a real energy E1C, and/or a radiation analysis device, for measuring any type of energy radiation emitted by the emitter device 11 at the irradiated target zone. Still according to this specific example, the device 12 further comprises as an analysis and recording means A an image analysis device, for analysing the real effect A1C obtained at the irradiated target zone. The measurement and analysis device 12 according to the invention is in all the cases capable of recording this measured energy E1C and analysed effect A1C data, and transmits these two types of data to the controller device 13 of the system.

This controller device 13 thus comprises the real data of the irradiated target zone C, which it received from the measurement and analysis device 12, and it further comprises predetermined data that was loaded into this device 13 at the beginning of the irradiation method, which predetermined data comprises the predetermined main energy thresholds E2S1, E2S2. . . . E2Si. . . . E2Sn which are respectively associated with each of the zones S1, S2. . . . Si. . . . Sn of the surface S to be irradiated, as well as the target effect O to be obtained. For the purpose of controlling the emitter device 11 in real time, this controller device 13 comprises means for comparing the measurement of the real energy E1C to the predetermined main energy threshold E2C associated with the target zone C, and means for comparing the analysis of the real effect A1C to the target effect O. Thus, the device 13 is capable of controlling the emitter device 11 in real time by carrying out various actions, which are a function of the real energy E1C and at the same time of the real effect A1C at the target zone C. In particular, according to a first case, if the controller device 13 determines, via its various comparison means, that the real energy E1C of the target zone C is less than the predetermined main energy threshold E2C for this zone, and that at the same time the real effect A1C at this zone does not correspond to the target effect O, it controls the emitter device 11 so that the latter continues to emit energy radiation onto the target zone, and it modulates the power and/or the intensity of this radiation, until the target effect O is obtained.

According to a second case, if the controller device 13 determines that the real energy E1C of the target zone C corresponds to the predetermined main energy threshold E2C for this zone, but that the real effect A1C does not correspond to the target effect O, it controls the emitter device 11 so that the latter continues to emit energy radiation onto the target zone, and it modulates the power and/or the intensity of this radiation, until the target effect O is obtained.

According to a third case, if the controller device 13 determines that the real energy E1C of the target zone C corresponds to the predetermined main energy threshold E2C, and that at the same time the real effect A1C at this zone corresponds to the target effect O, it controls the emitter device 11 so that the latter stops the emission of the energy radiation onto the target zone O, since the target effect O has been obtained.

Finally, according to a fourth case, if the controller device 13 determines that the real energy E1C of the target zone C is less than the predetermined main energy threshold E2C, but that the real effect A1C corresponds to the target effect O, it controls the emitter device 11 so that the latter stops the emission of the energy radiation onto the target zone O, even though the predetermined main energy threshold E2C has not been reached, since the real energy parameters of the radiation R have allowed the target effect O to be obtained.

According to one embodiment, this controller device 13 is a human-machine interface, which can for example be a computer, a tablet or a smartphone, or a robot.

The device 13 thus allows an advantageous energy gain, since it is capable of stopping the irradiation of the target zone/surface when it is determined that the expected effect has been obtained, independently of the base energy thresholds inputted into the device 13. The emission of useless radiation is thus advantageously limited, as soon as the target effect is obtained, which is justified from a financial and environmental point of view. The device 13 is also capable of independently controlling the plurality of emitting sources 111 of the emitter device 11, according to the analysed real effect at the target zone C during the irradiation process, to adapt this target zone. For example, if the controller device 13 determines that the real effect A1C at the target zone C corresponds to the target effect O on a part of this target zone, but that this target effect O has not yet been obtained on the totality of this zone, it can act on the emitter device 11 to deactivate the LEDs 111 located above the part of the target zone for which the target effect O has been obtained, and increase the power and/or the energy intensity of the LEDs 111 located above the part of the target zone for which the target effect O has not yet been obtained. Thus, the target zone C effectively irradiated is reduced.

According to the invention, the measurement and analysis device 12 is also capable of measuring the collateral real energy E3 of one or more zones, for example of a zone Si, which is adjacent/collateral to the irradiated target zone C. This measurement is recorded in the device 12, which transmits it to the control device 13. In the latter, secondary energy thresholds E4S1, E4S2, E4Si. . . . E4Sn, associated with each of the zones forming the surface S, have previously been inputted: the control device 13 is thus capable of comparing the collateral energy E3Si measured at the zone Si adjacent to the irradiated target zone C to the secondary energy threshold E4Si of this zone. According to the result of this comparison, it can modulate the emitting source 11 to affect in one direction or in the other the collateral real energy E4Si of this zone adjacent to the irradiated target zone C: it can reduce the power and/or the intensity of the radiation of the source 11, to reduce this collateral energy E3Si, if it determines that it has reached the secondary energy threshold E4Si of this zone, or on the contrary it can increase the power and/or the intensity of the radiation of the source 11, to increase this collateral energy E3Si, if it is determined that it has not yet reached the secondary energy threshold E4Si of this zone. Thus, the interpretation of the measurements coming from secondary sensors related to the energy generated collaterally to the irradiated target zone C allows to preserve the integrity of the target.

It is thus understood that, according to the invention, each of the zones forming the surface S to be irradiated is associated with two types of predetermined energy thresholds, inputted into the control device 13: first predetermined energy thresholds E2, called main energy thresholds, and second predetermined energy thresholds E4, called secondary energy thresholds.

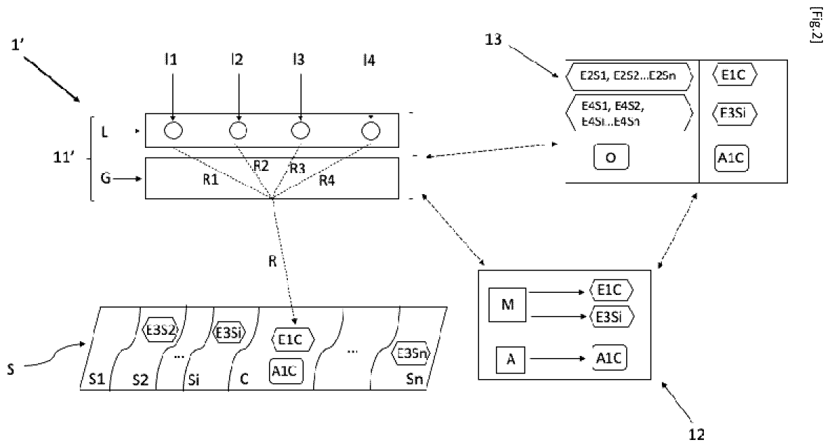

The energy radiation R emitted by the emitter device 11 can be radiation of visible light, infrared, gamma, ultraviolet, laser, or convective or conductive thermal deployment. FIG. 2 illustrates another example of the system 1′ of the invention, and which corresponds to the system as illustrated in FIG. 1 wherein the emitter device 11′ consists of a support array L grouping together four laser sources 11, 12, 13 and 14, and of an optical galvanometer G. Each of these four laser sources 11, 12, 13 and 14 respectively emits an energy radiation R1, R2, R3 and R4. These four radiations R1, R2, R3 and R4 are combined into one single energy radiation R by the optical galvanometer G, this unique radiation R being directed towards the target zone to be irradiated.

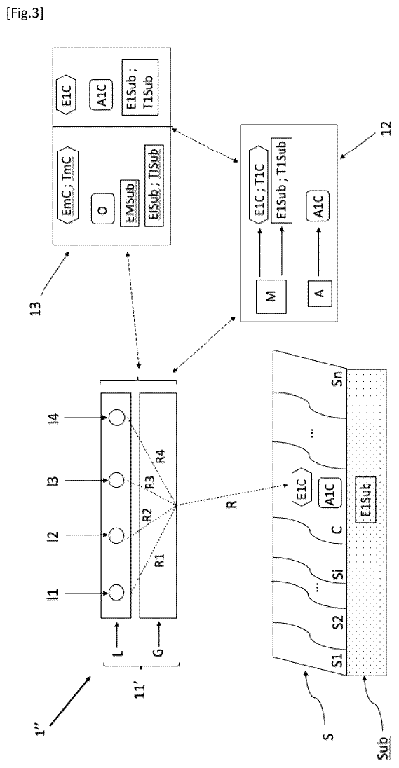

According to a particular embodiment of the invention, illustrated by the system 1″ of FIG. 3, the target zone C to be irradiated corresponds to a zone of a surface S of a layer of a material, which layer of material is deposited over a substrate Sub, which corresponds for example to at least one other layer of another material, distinct from the material to be irradiated. The system 1″ according to the invention is then able to irradiate in a controlled manner the target zone C of the surface of the layer of material that is exposed to open air and which is deposited over the substrate Sub. The system 1″ is further able to evaluate the state of the substrate Sub according to the progress of irradiation of the layer of material that covers it. Preferably, this evaluation of the state of the substrate Sub is carried out simultaneously with irradiation of the layer of material that covers it. In particular, this allows ensuring that the substrate Sub is not damaged by the irradiation of the layer of material that covers it, at least partially.

For example, the evaluation of the state of the substrate Sub is implemented by visual inspection of its state, for example its surface condition, and/or by inspection of its physico-chemical properties, such as its temperature or its viscosity.

Moreover, it should be noted that the material deposited over the substrate Sub is preferably liquid ink.

Thus, according to this particular example of the invention, it is possible to enter different parameters in the controller device 13 of the system, or in a recording unit to which the controller device 13 has access. Preferably, a predetermined main energy threshold EmC associated with the target zone C to be irradiated is entered therein. Preferably, this predetermined main energy threshold corresponds to a minimum energy threshold.

Furthermore, the target effect O to be obtained by irradiation at this target zone C is preferably, also entered in the recording unit. A predetermined duration TmC is also entered in the controller device 13, this predetermined duration TmC being associated with the minimum energy threshold EmC of the target zone C, and preferably corresponds to a minimum threshold duration.

For example, the minimum energy threshold EmC corresponds to a minimum threshold temperature, and the target effect O to be obtained corresponds to the polymerisation of the material of the target zone C.

Thus, when one of the emitter devices 11 described in the examples presented before in the description irradiates the target zone C, the measurement and analysis device 12 of the system 1″ of the invention, which is for example a thermal camera, measures the real energy E1C at this target zone C, i.e. it measures its real temperature, to ensure that the latter is equal to or substantially higher than the minimum threshold temperature EmC predefined for this zone. The measurement and analysis device 12 also controls the duration T1C during which the target zone C is irradiated at this minimum threshold temperature EmC, to ensure that the target zone C is irradiated at the minimum threshold temperature EmC over the minimum threshold duration TmC predefined for this zone. The measurement and analysis device 12 further controls the real effect A1C obtained at the irradiated zone, in order to ensure that the latter effectively corresponds to the target effect O to be obtained entered beforehand in the controller device 13.

Moreover, still according to this particular example of the invention, a maximum energy threshold EMSub and an intermediate energy threshold ElSub, preferably, are further entered in the controller device 13, these two thresholds being associated with the substrate Sub. For example, this maximum energy threshold EMSub and this intermediate energy threshold ElSub respectively correspond to a maximum temperature and to an intermediate temperature that the substrate Sub is capable of reaching. In addition, a maximum duration TlSub associated with the intermediate energy threshold ElSub is preferably also entered in the controller device 13.

Thus, concomitantly with the analysis of the material of the irradiated target zone C, when the emitter device 11′ irradiates the target zone C, the measurement and analysis device 12 measures the effective energy E1Sub at the substrate Sub, i.e. it measures its real temperature, to determine that the latter does not exceed the maximum threshold temperature EMSub predefined for this substrate Sub. Also, the measurement and analysis device 12 determines the duration T1Sub during which the substrate Sub reaches the predefined intermediate threshold temperature ElSub, to verify that this intermediate temperature is not reached over a duration longer than the predefined maximum threshold duration TlSub.

The measurement and analysis device 12 transmits all of the measured and recorded data, associated with the target zone C of the material to be irradiated and to the substrate Sub, to the controller device 13. The latter is then capable of adapting the orientation and/or the power and/or the intensity of the emitter device 11′, in order to polymerise the target zone C without damaging the substrate Sub.

Several exemplary embodiments of the method and of the irradiation system according to the invention for various uses are presented below. It is understood that these examples are not limiting, and that the invention can be implemented for any type of use involving the energy irradiation of a surface to obtain a given effect.

### First Exemplary Embodiment

The method according to the invention can be implemented in the case of the application of a layer of suitable polish onto a target zone C, which can correspond to one or more nails of a hand and/or of a foot, with the goal of obtaining a target effect O that corresponds to the solidification of the layer of polish, by a process of polymerisation via irradiation.

In this first example, the emitter device 11 is a lamp that emits ultraviolet radiation (UV) towards the target zone C which corresponds to one or more nails covered with a layer of polish, and which consists of a multitude of UV LEDs 111.

The measurement and analysis device 12 is a UV radiation probe doubled by a thermal camera, which comprises a module for measuring the UV dose and the real temperature E1C at the surface of the irradiated nail(s) covered with polish, and a module for visual analysis of the state of the polymerisation A1C of the layer of polish at this zone.

As for the controller device 13, it is a computer, into which the predetermined temperature E2C that allows a priori to obtain the total polymerisation of the layer of polish on the target zone C, as well as the target visual state O of the final polymerisation of the layer of polish at this zone, have been inputted. This computer 13 also comprises means for comparing the real temperature data E1C with respect to the predetermined temperature data E2C for the target zone C to be irradiated, as well as means for comparing the real state A1C of the polymerisation of the layer of polish with respect to the expected state O of polymerisation for this zone.

In this example of use of the invention, the UV lamp 11 emits UV radiation towards the determined target zone C. The thermal camera associated with the UV probe 12 thus measures the real temperature E1C of the target zone C, and analyses the real state A1C of the polymerisation of the layer of polish at this zone. It records these two types of information, and transmits them to the control computer 13. The latter is thus capable of determining, via its comparison means, whether the layer of polish of the target zone has been polymerised over the entirety of the zone, or whether one or more portions of this zone still require an irradiation to obtain the expected final effect O. It is thus capable of increasing the power and/or the intensity of the UV LEDs 111 of the lamp 11, or even of activating LEDs that are turned off, and which are positioned above the portion(s) of the target zone for which the layer of polish has not yet been totally polymerised, and inversely, of reducing the power and/or the intensity of the UV LEDs 111, or even of deactivating certain LEDs, which are positioned above the portion(s) of the target zone for which the layer of polish has been totally polymerised or above zones of epidermis.

Moreover, according to a specific embodiment of this example, the thermal camera associated with the UV probe 12 is capable of measuring and of recording the collateral real energy of zones around the target nail, corresponding in particular to zones of skin around the nail. This data is transmitted to the control computer 13, which thus compares it to the secondary energy threshold data associated with these zones of skin. If the computer 13 determines, after this comparison step, that the effective collateral energy in these zones of skin has reached the corresponding secondary thresholds, it then modulates the power and/or the intensity of the UV LEDs 111 above the irradiated nail zone to reduce the energy felt at the collateral level, on the zones of skin. Thus, via the thermal vision, the UV radiation adjacent to the target zone C is controlled, avoiding potential local burns.

Thus, the method and the irradiation system according to the invention advantageously allow a substantial energy gain in the field of cosmetics, in particular of nail care, since the control of the emitter devices 11 used to polymerise the layers of polish on the nails can be adapted on demand in a closed loop, according to the change in the real situation. It also allows to minimise the risks of cancer of the skin related to UV exposure and the risk of burns related to the adjacent UV or IR radiation.

### Second Exemplary Embodiment

The method according to the invention can also be implemented in the case of the manufacturing of a part by an additive manufacturing method, for example to manufacture semiconductors in the field of microelectronics. Such a part in particular produced by solidification of the layer(s) of material added according to the technique of additive manufacturing, via polymerisation by irradiation.

In this second example, the system for irradiation in a closed loop comprises an emitter device 11 that is a source that emits laser radiation towards the target zone C, which corresponds to one or more zones of a layer of material deposited by additive manufacturing, this source 11 consisting of a multitude of laser sources 111. It also comprises a measurement and analysis device 12, which is a thermal camera as described in detail in the first example above. And it further comprises a controller device 13, which is a computer as also described in the first example above.

In this example of use of the invention, the irradiation method comprises the same steps as the irradiation method of the preceding example. It is the laser sources 111 of the emitter device 11 that are controlled (activated, deactivated, modulation of their power and/or of their intensity) by the control computer 13, according to the predetermined temperature E2C capable of completely polymerising the target zone, and the expected visual state O corresponding to the complete polymerisation of this zone, while taking into account the real temperature E1C measured at this target zone and the real state of the polymerisation at this zone. The control device 13 thus allows to manage the laser source 11 so that the emission of laser radiation R that is useless since it is located at a totally polymerised part of the target zone to be limited, or even stopped.

This irradiation system, in this case of application to the field of additive manufacturing, can also be capable of measuring and of analysing the collateral energy around the target zone being manufactured, with respect to secondary energy threshold data associated with the zones adjacent to this target zone.

A non-negligible energy and financial gain can be obtained in the field of additive manufacturing. The selective control of the radiation also allows to minimise the overall rise in temperature of the target. This has a direct impact on the integrity of the semiconductor module, and opens up a range of potentially eco-friendly products for the manufacturing of these semiconductors.

1. A method for controlled selective irradiation of a target zone of a surface of a layer of material to allow local radiation of said target zone with a view to obtaining a target effect, consisting in polymerisation of the layer of material, said method being implemented by a system comprising an emitter device, at least one measurement and analysis device and a controller device, said method comprising:
A) segmenting said surface into a plurality of zones;
B) inputting into said controller device predetermined main energy thresholds respectively associated with each of said zones, and inputting said target effect to be obtained;
C) choosing said target zone among the zones and combinations of the zones;
D) irradiating said target zone by emission of energy radiation by said emitter device, said emission being controlled by said controller device with the goal of reaching said predetermined main energy thresholds;
E) measurement and recording in real time, by said measurement and analysis device, of real energy generated by the energy radiation at said target zone;
F) analysis and recording, by said measurement and analysis device, of a real effect obtained at said irradiated target zone;
G) transmitting the measurement of said real energy and the analysis of said real effect to said controller device;
H) controlling in real time of said emitter device by said controller device during the irradiation method, while taking into account said measurement of the real energy and said analysis of the real effect received,
said measurement of real energy being compared to the predetermined main energy threshold associated with said target zone, and said analysis of the real effect being compared to said target effect, so that:
H1) if said main energy threshold is not reached and said target effect is not obtained, the emission of energy radiation onto said target zone continues and a power and/or an intensity of said energy radiation is modulated to obtain said target effect;
H2) if said main energy threshold is reached but said target effect is not obtained, the emission of energy radiation onto said target zone continues and the power and/or the intensity of said energy radiation is modulated to obtain said target effect;
H3) if said main energy threshold is reached and the target effect is obtained, the emission of energy radiation onto said target zone is stopped;
H4) if said main energy threshold is not reached but said target effect is obtained, the emission of energy radiation onto said target zone is stopped.

2. The method according to claim 1, further comprising:
A′) inputting into said controller device predetermined secondary energy thresholds respectively associated with each of said zones;
B′) measurement and recording in real time, by said measurement and analysis device, of collateral real energy, generated at least at one zone of said plurality of zones that is adjacent to said target zone, said collateral real energy being generated by the energy radiation irradiating said target zone;
C′) transmitting the measurement of said collateral real energy to said controller device;
D′) control in real time of said emitter device by said controller device during the irradiation method, while taking into account the measurement of said collateral real energy), this measurement of said collateral real energy being compared to the predetermined secondary energy threshold associated with the at least one zone of said plurality of zones that is adjacent to said target zone, so that:
if said secondary energy threshold of said at least one zone adjacent to said target zone is reached, the power and/or the intensity of said energy radiation irradiating said target zone are modulated to reduce said collateral real energy.

3. (canceled)

4. (canceled)

5. The method according to claim 1, wherein said target zone corresponds to the totality of the surface.

6. The method according to claim 1, wherein said emitter device is stationary and chosen from a group consisting of an array comprising a plurality of independent emitting sources and at least one emitting source associated with an optical galvanometer.

7. The method according to claim 6, wherein, said emitter device is an array comprising a plurality of independent emitting sources, and said independent emitting sources are LEDs.

8. The method according to claim 1, wherein said emitter device is mobile.

9. The method according to claim 1, wherein said measurement and analysis device is a thermal and/or radiative imaging sensor, associated with an image analysis module.

10. The method according to claim 1, wherein said controller device is a human-machine interface.

11. The method according to claim 1, wherein said energy radiation is chosen from a group consisting of radiation of visible light, infrared, gamma, ultraviolet, laser, microwaves, X-rays, and convective or conductive thermal deployment.

12. A system for controlled selective irradiation of a target zone of a surface of a layer of material, said surface being segmented into a plurality of zones, said system being configured to implement the method according to claim 1, said system comprising:
an emitter device, configured to irradiate said target zone by energy radiation,
at least one measurement and analysis device, configured to measure the real energy generated by the energy radiation at said target zone and the collateral real energy generated at least at one zone of said plurality of zones that is adjacent to said target zone, as well as to analyse the real effect obtained at said irradiated target zone,
a controller device, configured to receive main and secondary predetermined energy thresholds, respectively associated with each of said zones and a target effect to be obtained, as well as to receive the measurement of said real energy and of said collateral real energy, as well as the analysis of said real effect,
said controller device comprising means for comparing said measurement of real energy to the predetermined main energy threshold associated with said target zone, said measurement of the collateral real energy to the predetermined secondary energy threshold of the at least one zone adjacent to said target zone, and said analysis of the real effect to said target effect,
said controller device being further configured to control said emitter device in real time during the irradiation method by stopping the emission of said energy radiation, and/or by modulating the power and/or the intensity of said energy radiation, and/or by selective modulation of the irradiated zones.

13. (canceled)

14. (canceled)

15. The system according to claim 12, wherein said measurement and analysis device comprises:
-at least one measurement and recording means configured to measure said real energy generated by the energy radiation at said target zone, and said collateral real energy at least at one zone adjacent to said target zone, and
at least one analysis and recording means configured to analyse said real effect obtained at said irradiated target zone.
